(19) United States
(12) Patent Application Publication
(10) Pub. No.: US 2005/0224944 A1
(43) Pub. Date: Oct. 13, 2005

(54) Stacked semiconductor device

(75) Inventors: Jin-Chyung Biar, Taipei County (TW); Wu-Chiang Yao, Taipei County (TW); Chi-Pang Huang, Taoyuan County (TW)

Correspondence Address: BACON & THOMAS, PLLC, 625 SLATERS LANE, FOURTH FLOOR, ALEXANDRIA, VA, 22314, US

(73) Assignee: STACK DEVICES Corp., Miaoli County (TW)

(21) Appl. No.: 10/822,712

(22) Filed: Apr. 13, 2004

(51) Int. Cl. H01L 23/495

(52) U.S. Cl. 257/686

(57) ABSTRACT

A stacked semiconductor device has a substrate having a conductor pattern and a cavity. A first die is received in the cavity of the cavity of the substrate and is electrically connected to the conductor pattern via wires. An adhesive layer is printed on a top of the first die. A second die is stacked on the first die via the adhesive layer and is electrically connected to the conductor pattern via wires, and An insulating layer provided on the substrate, wherein the insulating layer cover the first die and the second die and has a portion thereof received in the cavity to bond the first die.

### BACKGROUND OF THE INVENTION

1. Field of the Invention

The present invention relates generally to a semiconductor device, and more particularly to a stacked semiconductor device for thinner package.

2. Description of the Related Art

A conventional stacked semiconductor device has a substrate on which a plurality of dies are stacked and electrically connected to a conductor pattern on the substrate via gold wires. Adhesive layers are provided on the substrate and between the stacked dies to bond the dies.

The stacked dies shorten the total width thereof but increase the height thereof. The wires connecting the upper die to the conductor pattern are longer that the electrical signals transmitting via the longer wires are poorer than the shorter wires.

### SUMMARY OF THE INVENTION

The primary objective of the present invention is to provide a stacked semiconductor device, which has a die stack and the height of the stack is shorter than the conventional one.

According to the objective of the present invention, a stacked semiconductor device comprises a substrate having a conductor pattern and a cavity. A first die is received in the cavity of the cavity of the substrate and is electrically connected to the conductor pattern via wires. A second die is stacked on the first die and is electrically connected to the conductor pattern via wires, and An insulating layer provided on the substrate, wherein the insulating layer cover the first die and the second die and has a portion thereof received in the cavity to bond the first die.

### BRIEF DESCRIPTION OF THE DRAWINGS

FIG. 1 to FIG. 7 are sectional views of a first preferred embodiment of the present invention, showing how the dies stacked on the substrate;

FIG. 8 is a sectional view of a second preferred embodiment of the present invention;

FIG. 9 is a sectional view of a third preferred embodiment of the present invention, and

FIG. 10 is a top view of the third preferred embodiment of the present invention.

### DETAILED DESCRIPTION OF THE INVENTION

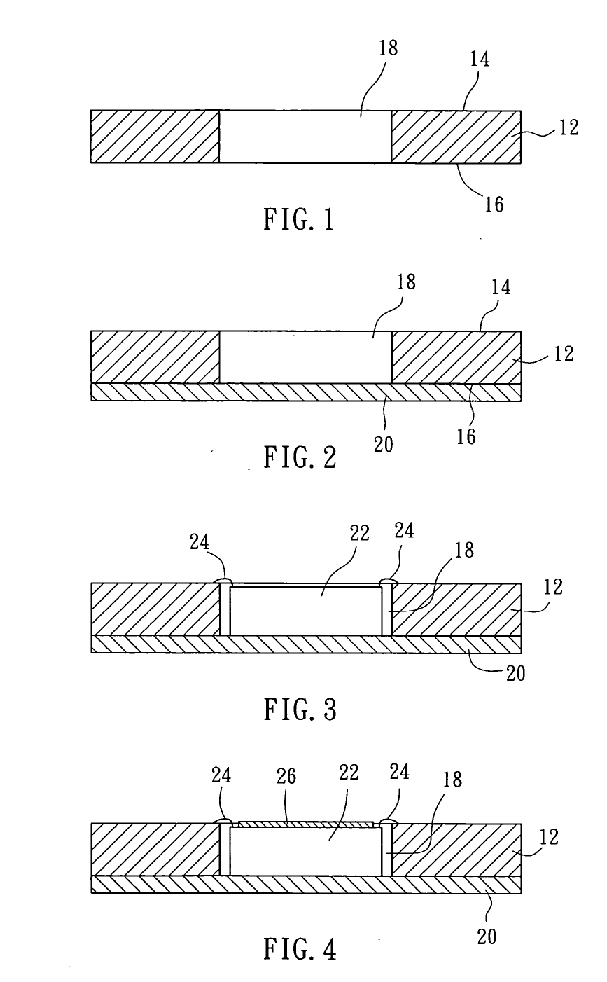

FIG. 1 to FIG. 7 are shown as a flow chart that help the one who may concern our invention to understand the structure of a stacked semiconductor device 10 of the first preferred embodiment of the present invention.

As shown in FIG. 1, the stacked semiconductor device 10 has a substrate 12 on which a conductor pattern (not shown) is provided. The substrate 12 has a first side 14 and a second side 16. The substrate 12 is provided with a cavity 18 that is open at both of the first side 14 and the second side 16.

As shown in FIG. 2, a peelable temporary base 20 is attached on the second side 16 of the substrate 12 and seals an end of the cavity 18. The temporary base 20 is a polyimide tape (PI tape) in the present preferred embodiment.

As shown in FIG. 3, a first die 22 is received in the cavity 18 of the substrate 12 and is bonded on the temporary base 20. A plurality of gold wires 24 are electrically connected the first die 22 and the conductor pattern of the substrate 12.

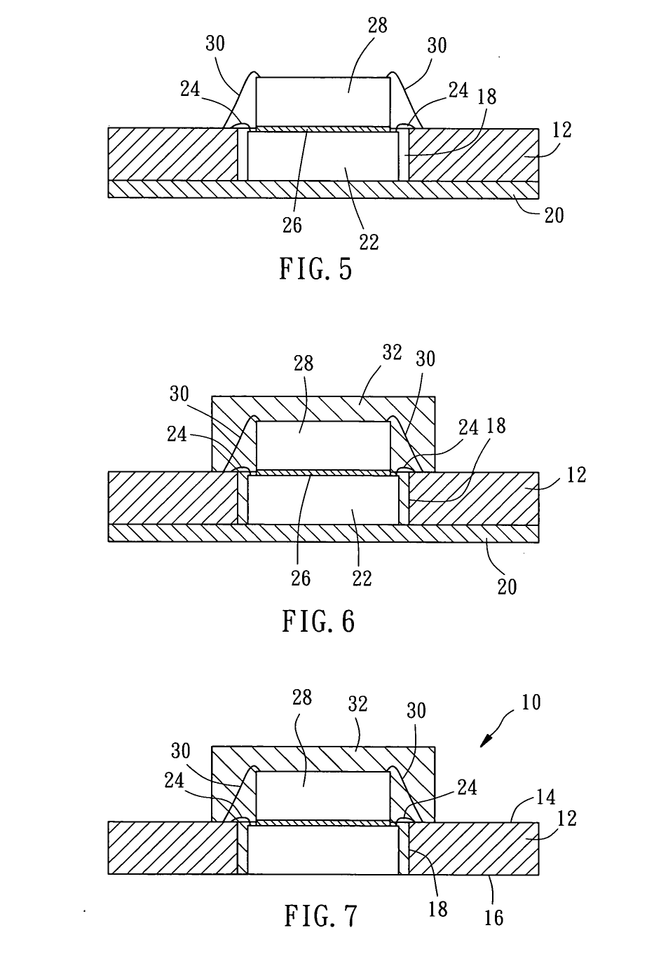

And then, as shown in FIG. 4, an adhesive layer 26 is printed on a top of the first die 22. The adhesive layer 26 is made of epoxy compound, silicon polymer or other suitable die attached materials. A second die 28 is attached on the adhesive layer 26 and gold wires 30 are electrically connected the second die 28 and the conductor pattern of the substrate 12, as shown in FIG. 5.

The step of wire bonding between the first die 22 and the conductor pattern can shift to here. In other words, the wire bonding steps of the first die 22 and the second die 30 are made in the same time.

As shown in FIG. 6, an insulating layer 32 is printed on the substrate 12 and filled in the cavity 18 to cover the first die 22, the second die 30 and the wires 24 and 32. The insulating layer 32 is made of epoxy compound, silicon polymer or other suitable materials. The insulating layer 32 and the adhesive layer 26 are preferred to be made of the same material.

At least, the temporary base 20 is removed to complete the stacked semiconductor device 10 of the first preferred embodiment of the present invention as shown in FIG. 7.

The first die 22 is embedded in the cavity 18 of the substrate 12 that makes the stacked semiconductor device 10 of the present invention shorter in height. The wires 30 electrically connected the second die 28 and the conductor pattern are shorter because the second die 28 is proximal to the substrate 12. The electrical signals transmitting via the wires 30 is better.

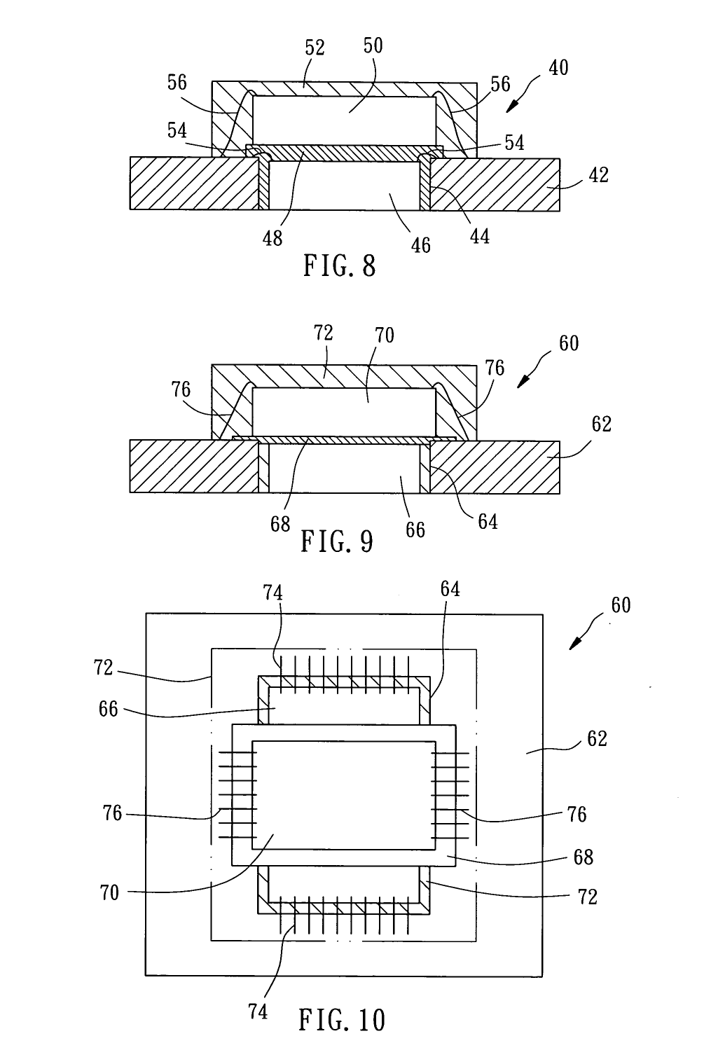

As shown in FIG. 8, a stacked semiconductor device 40 of the second preferred embodiment of the present invention has a substrate 42 with a cavity 44, a first die 46 received in the cavity 44 of the substrate 42, an adhesive layer 48, a second die 50 and an insulating layer 52. In the step of providing the adhesive layer 48, the adhesive layer 48 is coated on a top of the first die 46 and filled in the cavity 44 of the substrate 42. The adhesive layer 48 further is provided to cover gold wires 54, which connect the first die 46 and a conductor pattern (not shown) on the substrate 42. The insulating layer 52 is provided to cover the second die 50 and gold wires 56, which connect the second die 50 and the conductor pattern.

As shown in FIG. 9 and FIG. 10, a stacked semiconductor device 60 of the third preferred embodiment of the present invention, which is similar to the device 10 of the first preferred embodiment, has a substrate 62 with a cavity 64, a first die 66, an adhesive layer 68, a second die 70 and an insulating layer 72. The adhesive layer 68 is printed both on a top of the first die 66 and on the substrate 62. The second die 70 is attached to the adhesive layer 68, so that the second die 70 is mainly supported by the substrate 62 rather than the first die 66. The stack's structure is stronger and it still keeps the character of thinner die-to die thickness. As shown in FIG. 10, the first die 66 and the second die 70 are cross to let gold wires 74 and 76 connecting the first die 66 and the second die 70 to the conductor pattern (not shown) on the substrate 62 are not overlapped. The size of the second die 70 is not restricted by the first die 66.

The stacked semiconductor devices of the present invention can be applied to the ball grid array (BGA) substrates or the land grid array (LGA) substrates.

1. A stacked semiconductor device, comprising:
a substrate having a conductor pattern and a cavity;
a first die received in the cavity of the cavity of the substrate and electrically connected to the conductor pattern via wires;
a second die stacked on the first die and electrically connected to the conductor pattern via wires, and
an insulating layer provided on the substrate, wherein the insulating layer cover the first die and the second die and has a portion thereof received in the cavity to bond the first die.

2. The stacked semiconductor device as defined in claim 1, wherein the cavity is open at both opposite sides of the substrate.

3. The stacked semiconductor device as defined in claim 1, further comprising an adhesive layer between the first die and the second die.

4. The stacked semiconductor device as defined in claim 3, wherein the insulating layer has a portion thereon attached on the substrate and the second die has a portion thereof attached on the substrate via the insulating layer.

5. The stacked semiconductor device as defined in claim 3, wherein the insulating layer covers at least a portion of the wire.

6. The stacked semiconductor device as defined in claim 1, wherein the first die and the second die are cross.

7. A stacked semiconductor device, comprising:
a substrate having a conductor pattern and a cavity;
a first die received in the cavity of the cavity of the substrate and electrically connected to the conductor pattern via wires;
an adhesive layer provided on a top of the first die and received in the cavity to bond the first die;
a second die bonded on the adhesive layer and electrically connected to the conductor pattern via wires, and
an insulating layer provided on the substrate, wherein the insulating layer cover the second die.

8. The stacked semiconductor device as defined in claim 7, wherein the cavity is open at both opposite sides of the substrate.

9. The stacked semiconductor device as defined in claim 7, wherein the insulating layer has a portion thereon attached on the substrate and the second die has a portion thereof attached on the substrate via the insulating layer.

10. The stacked semiconductor device as defined in claim 7, wherein the insulating layer covers at least a portion of the wire.

11. The stacked semiconductor device as defined in claim 7, wherein the first die and the second die are cross.
